(19) United States
(12) Patent Application Publication
(10) Pub. No.: US 2024/0429075 A1
(43) Pub. Date: Dec. 26, 2024

(54) SUBSTRATE PROCESSING APPARATUS, METHOD FOR SUBSTRATE PROCESSING, AND METHOD FOR MANUFACTURING SEMICONDUCTOR DEVICE

(71) Applicant: Kioxia Corporation, Tokyo (JP)

(72) Inventors: Ryo ITO, Yokkaichi Mie (JP); Hiroshi FUJITA, Yokohama Kanagawa (JP); Tatsuhiko KOIDE, Kuwana Mie (JP)

(73) Assignee: Kioxia Corporation, Tokyo (JP)

(21) Appl. No.: 18/740,873

(22) Filed: Jun. 12, 2024

(30) Foreign Application Priority Data
Jun. 21, 2023 (JP) 2023-101669

(51) Int. Cl. H01L 21/67; H01L 21/311; H01L 21/66

(52) U.S. Cl. CPC H01L 21/67253; H01L 21/31111; H01L 21/67086; H01L 22/26

(57) ABSTRACT

A substrate processing apparatus according to an embodiment includes a processing tank configured to store a chemical and perform processing by immersing a substrate in the chemical, a holder configured to hold the substrate and having a lifting part, a chemical liquid supply device configured to supply the chemical, a light irradiation part configured to irradiate light to the substrate taken out from the processing tank, the substrate being taken out from the processing tank by the lifting part after immersing the substrate in the chemical, a light detection part configured to detect reflected light generated from the light being reflected by the substrate, and a control device configured to control an amount of chemical supplied by the chemical liquid supply device in response to a detection result of the light detection part.

### CROSS-REFERENCE TO RELATED APPLICATION(S)

This application is based upon and claims the benefit of priority from the prior Japanese Patent Application No. 2023-101669, filed on Jun. 21, 2023, the entire contents of which are incorporated herein by reference.

### FIELD

Embodiments described herein relate generally to a substrate processing apparatus, a method for substrate processing, and a method for manufacturing a semiconductor device.

### BACKGROUND

In some cases, a silicon nitride film is selectively etched with respect to a silicon oxide film of a substrate having a laminate in which the silicon nitride film and the silicon oxide film are alternately formed. In this case, a phosphoric acid solution is generally used as an etchant. In such an etching process, the phosphoric acid solution may be partially replaced and used a plurality of times.

### BRIEF DESCRIPTION OF DRAWINGS

FIG. 1 is a diagram schematically showing an overall configuration of a substrate processing apparatus according to an embodiment.

FIG. 2 is a schematic diagram showing a light irradiation part and a light detection part according to an embodiment.

FIG. 3 is a cross-sectional view of a substrate to be subjected to an etching process according to an embodiment.

FIG. 4 is a flowchart for explaining a method for substrate processing according to an embodiment.

FIG. 5 is a diagram for explaining methods for light irradiation and light detection according to an embodiment.

FIG. 6 is a flowchart for explaining a method for substrate processing according to an embodiment.

### DESCRIPTION OF EMBODIMENTS

Hereinafter, a substrate processing apparatus, a method for substrate processing, and a method for manufacturing a semiconductor device according to the present embodiment will be specifically described with reference to the drawings. In the following description, elements having substantially the same functions and configurations are denoted by the same reference signs or the same reference signs followed by alphabetic characters, and will be described redundantly only when necessary. Each of the embodiments described below exemplifies an apparatus and a method for embodying the technical idea of this embodiment. Various modifications may be made to an embodiment without departing from the spirit of the disclosure. These embodiments and modifications thereof are included in the scope of the disclosure described in the claims and equivalents thereof.

In the drawings, although the widths, thicknesses, shapes, and the like of the respective portions may be schematically represented in comparison with the actual embodiments for clarity of explanation, the drawings are merely examples, and do not limit the interpretation of the present disclosure. In the present specification and the drawings, elements having the same functions as those described with respect to the drawings already described are denoted by the same reference sings, and redundant descriptions thereof may be omitted.

In the present specification, the expression “a includes A, B, or C” does not exclude a case where a includes a plurality of combinations of A to C unless otherwise specified. Furthermore, these expressions do not exclude the case where a includes other elements.

In the present specification, horizontal refers to a direction horizontal to a bottom surface of an inner tank (XY direction), and vertical may refer to a direction) substantially perpendicular to the horizontal direction (Z direction.

The following embodiments and modifications can be combined with each other.

A substrate processing apparatus according to an embodiment includes a processing tank configured to store a chemical and perform processing by immersing a substrate in the chemical, a holder configured to hold the substrate and having a lifting part, a chemical liquid supply device configured to supply the chemical, a light irradiation part configured to irradiate light to the substrate taken out from the processing tank, the substrate being taken out from the processing tank by the lifting part after immersing the substrate in the chemical, a light detection part configured to detect reflected light generated from the light being reflected by the substrate, and a control device configured to control an amount of chemical supplied by the chemical liquid supply device in response to a detection result of the light detection part.

### First Embodiment

### [Substrate Processing Apparatus]

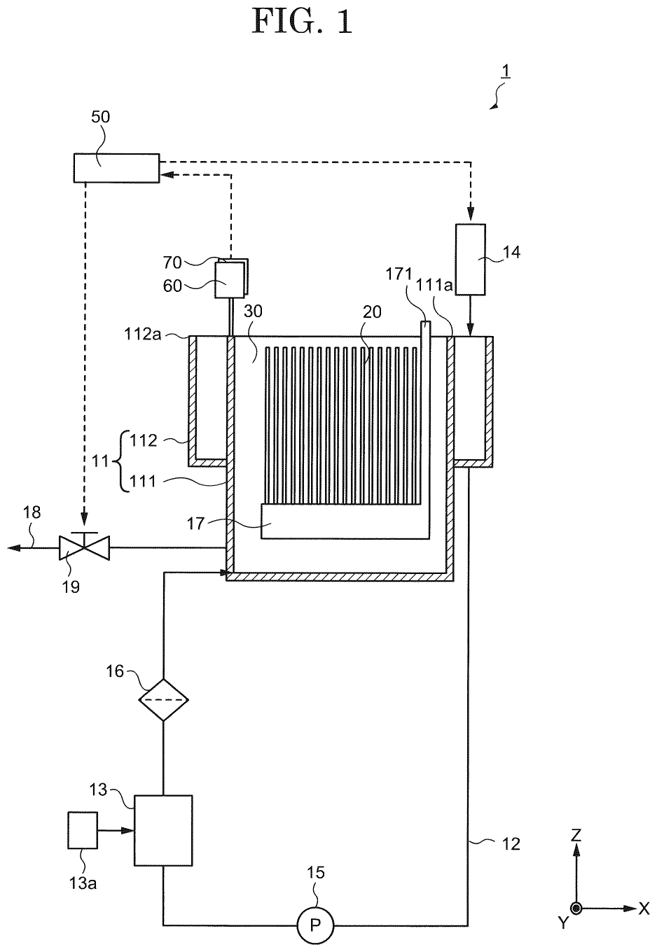

FIG. 1 is a diagram schematically showing an overall configuration of a substrate processing apparatus according to an embodiment. A substrate processing apparatus 1 according to the present embodiment is a batch-type processing apparatus, and is, for example, a wet etching processing apparatus that removes a silicon nitride film (not shown in FIG. 1) arranged on a substrate 20 with a solution 30 containing phosphoric acid (hereinafter referred to as a phosphoric acid solution). As shown in FIG. 1, the substrate processing apparatus 1 includes a processing tank 11, a circulation path 12, a heating part 13, a chemical liquid supply device 14, a pump 15, a filter 16, a holder 17, a discharge path 18, a valve 19, a control device 50, a light irradiation part 60, and a light detection part 70.

The processing tank 11 is a container having an inner tank 111 and an outer tank 112. The inner tank 111 is formed in a box shape having an upper end opening 111a. The inner tank 111 stores therein the phosphoric acid solution 30, that is, an etching solution (processing solution) of the silicon nitride film. Temperature, phosphoric acid concentration, and silica concentration of the phosphoric acid solution 30 stored in the inner tank 111 are optimized for etching the silicon nitride film arranged in the substrate 20.

The inner tank 111 is capable of accommodating the wafer-shaped (disk-shaped) substrate 20 in a vertical direction (a direction (YZ direction) in which a main surface is parallel to the vertical direction). Inside the inner tank 111, the holder 17 is capable of accommodating the multiple substrates 20 arranged in a plurality of rows in the horizontal direction (X direction) at predetermined intervals, and in FIG. 1, for example, the holder 17 holds 18 substrates 20 in the inner tank 111. However, the present disclosure is not limited thereto, and for example, a maximum of 50 substrates 20 may be accommodated in one inner tank 111.

The holder 17 may include a lifting part 171 that raises and lowers the held substrate 20 in the vertical direction (Z direction) with respect to the inner tank 111. By the lifting operation of the lifting part 171, the substrate 20 before an etching process can be automatically immersed in the phosphoric acid solution 30 stored in the inner tank 111, and the substrate 20 after the etching process can be automatically taken out from the inner tank 111.

When the substrate 20 is immersed in the phosphoric acid solution 30, the silicon nitride film arranged on the substrate 20 is dissolved in the phosphoric acid solution 30 and removed from the substrate 20. Therefore, the inner tank 111 has a depth sufficient to completely immerse the vertically accommodated substrate 20 in the phosphoric acid solution 30. The upper end opening 111a of the inner tank 111 is higher than the upper end of the vertically accommodated substrate 20.

The outer tank 112 has an upper end opening 112a that surrounds the upper end opening 111a of the inner tank 111 over the entire circumference. The outer tank 112 collects the phosphoric acid solution 30 overflowing from the upper end opening 111a of the inner tank 111.

The circulation path 12 communicates with a bottom portion of the outer tank 112 and a bottom portion of the inner tank 111, and circulates the phosphoric acid solution 30 with respect to the processing tank 11. Specifically, the circulation path 12 recirculates the phosphoric acid solution 30 flowing out to the outer tank 112 to the inner tank 111. During this reflux process, the phosphoric acid solution 30 passes through the heating part 13, the pump 15, and the filter 16.

The heating part 13 is arranged in the middle of the circulation path 12. The heating part 13 heats the phosphoric acid solution 30. The heating part 13 is, for example, a line heater using a halogen lamp as a heat source.

In the present embodiment, a heating control part 13a adjusts heating temperature of the heating part 13 so that the phosphoric acid solution 30 is heated at a constant temperature. The phosphoric acid solution 30 (heating solution) heated by the heating part 13 is supplied to the inside of the inner tank 111 via the filter 16.

The chemical liquid supply device 14 is arranged above the outer tank 112. The chemical liquid supply device 14 supplies the chemical to the outer tank 112. The chemical liquid supply device 14 is, for example, a nozzle or a pipe connected to a chemical liquid storage tank. The chemical is, for example, water, a phosphoric acid liquid in which phosphoric acid is condensed, an additive, or a phosphoric acid solution in which the phosphoric acid liquid and the additive are mixed. Concentration of the phosphoric acid solution 30 collected into the outer tank 112 is changed by evaporation of moisture and an etching process in the inner tank 111. For example, when a silicon nitride film 222 melts, concentration of silica in the phosphoric acid solution 30 increases. In addition, concentration of the additive or the like adsorbed on the substrate 20 in the phosphoric acid solution 30 decreases.

In order to adjust the concentration of the phosphoric acid solution 30 refluxed to the inner tank 111 to an optimum concentration for selective etching of the silicon nitride film, water may be supplied from the chemical liquid supply device 14. The chemical liquid supply device 14 may supply a phosphoric acid liquid or an additive to the outer tank 112 instead of water. Further, the chemical liquid supply device 14 may supply the phosphoric acid solution 30, which is adjusted in advance to the optimum concentration for etching the silicon nitride film, that is, the same phosphoric acid concentration as the phosphoric acid solution 30 initially stored in the inner tank 111 (the phosphoric acid solution 30 before the heating solution is supplied), to the outer tank 112. Amounts of water, a phosphoric acid liquid, an additive, or a phosphoric acid solution supplied by the chemical liquid supply device 14 are controlled by the control device 50.

The pump 15 is arranged on an upstream side of the circulation path 12 with respect to the heating part 13. When the pump 15 sucks the phosphoric acid solution 30 from the outer tank 112, the phosphoric acid solution 30 collected into the outer tank 112 moves to the heating part 13. In addition, the pump 15 pressurizes the phosphoric acid solution 30 heated by the heating part 13 to supply this phosphoric acid solution 30 to the inner tank 111.

The filter 16 is arranged on a downstream side of the circulation path 12 with respect to the heating part 13. The filter 16 removes particles contained in the phosphoric acid solution 30 in the circulation path 12. The particles also include, for example, silica dissolved in the phosphoric acid solution 30 by the etching process of the substrate 20. The filter 16 may be arranged on the upstream side of the circulation path 12 with respect to the heating part 13.

The discharge path 18 is connected to the inner tank 111, and discharges the phosphoric acid solution 30 to a drain, for example, when a part of the phosphoric acid solution 30 used in the etching process is replaced. The valve 19 is arranged in the discharge path 18. A discharge amount of the phosphoric acid solution 30 by the valve 19 is controlled by the control device 50.

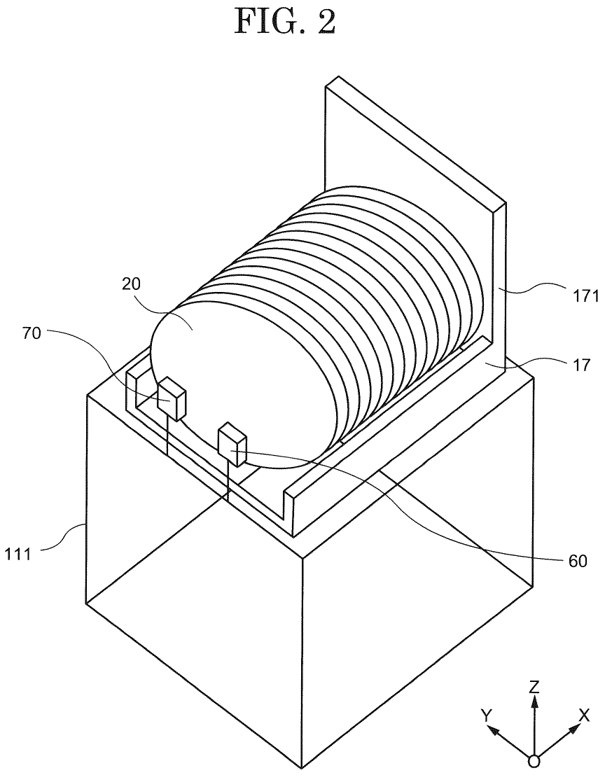

FIG. 2 is a schematic diagram showing a light irradiation part and a light detection part according to the present embodiment. As shown in FIG. 1 and FIG. 2, the light irradiation part 60 and the light detection part 70 are arranged on the upper end opening 111a of the inner tank 111. The light irradiation part 60 is arranged to face the substrate 20 so as to be able to irradiate light to the substrate 20 immediately taken out from the inner tank 111 by the lifting operation of the lifting part 171 after the etching process. The light detection part 70 is arranged to face the substrate 20 so as to be able to detect reflected light of the light incident on the substrate 20. Angle between the light irradiated by the light irradiation part 60 and the substrate 20 is not particularly limited. Arrangement of the light irradiation part 60 and the light detection part 70 with respect to the substrate 20 may be within a range in which the light detection part 70 can detect the reflected light of the light irradiated by the light irradiation part 60. A position at which the light irradiation part 60 irradiates light to the substrate 20 is not particularly limited. Positions of the light irradiation part 60 and the light detection part 70 with respect to the substrate 20 may always be constant.

The light irradiation part 60 and the light detection part 70 are arranged so as to face a back surface of the substrate 20 opposite to the main surface (a surface on which a laminate including the silicon nitride film is formed). The light irradiated by the light irradiation part 60 is reflected on the back surface of the substrate 20 and is detected by the light detection part 70. The substrate 20 immediately taken out from the inner tank 111 by the lifting operation of the lifting part 171 after the etching process includes the phosphoric acid solution 30 on the surface (main surface and back surface) of the substrate 20. Therefore, the light irradiated by the light irradiation part 60 is reflected to the back surface of the substrate 20 through the phosphoric acid solution 30 on the surface of the substrate 20, and is detected by the light detection part 70. Reflectance obtained from intensity of the reflected light detected by the light detection part 70 varies depending on an amount and composition of the phosphoric acid solution 30 on the surface of the substrate 20. For example, when the amount of the phosphoric acid solution 30 remaining on the surface of the substrate 20 is large, the reflectance becomes small, and when the concentration of the composition of the phosphoric acid solution 30 remaining on the surface of the substrate 20 is high, the reflectance may become small. Alternatively, when the amount of the phosphoric acid solution 30 remaining on the surface of the substrate 20 is large, the reflectance increases, and when the concentration of the composition of the phosphoric acid solution 30 remaining on the surface of the substrate 20 is high, the reflectance may increase.

A wavelength of the light irradiated by the light irradiation part 60 is not particularly limited. The wavelength of the light irradiated by the light irradiation device 60 may be, for example, 350 nm or more and 2500 nm or less. The light irradiated by the light irradiation part 60 may include light of a single wavelength, or may include light of a plurality of wavelengths. Intensity of the light irradiated by the light irradiation part 60 can be appropriately selected. A light source of the light irradiation part 60 is not particularly limited. The light source of the light irradiation part 60 may be, for example, a halogen lamp, a deuterium lamp, a xenon lamp, or the like.

A wavelength of the light detected by the light detection part 70 is not particularly limited. The light detected by the light detection part 70 may be light of a single wavelength or light of a plurality of wavelengths. A light detector of the light detection part 70 may be, for example, photomultiplier tubes, silicon photodiodes, InGaAs photodiodes, PbS photoconductive devices, and the like. Reflectance obtained from intensity of the reflected light detected by the light detection part 70 is supplied to the control device 50.

The control device 50 controls the amounts of the water, the phosphoric acid liquid, the additive, or the phosphoric acid solution supplied by the chemical liquid supply device 14, and the discharge amount of the phosphoric acid solution 30 by the valve 19 in response to the reflectance obtained from the intensity of the reflected light detected by the light detection part 70.

The substrate processing apparatus according to the present embodiment can obtain reflectance by irradiating light to the substrate 20 immediately after the etching process by the light irradiation part 60 and detecting the reflected light by the light detection part 70. Since the reflectance varies depending on an amount and composition of the phosphoric acid solution 30 remaining on the surface of the substrate 20, a state of the phosphoric acid solution 30 after the etching process that cannot be detected by the existing method can be grasped. By controlling amounts of the water, the phosphoric acid liquid, the additive, or the phosphoric acid solution supplied by the chemical liquid supply device 14 and a discharge amount of the phosphoric acid solution 30 by the valve 19 in response to the reflectance, a state of the phosphoric acid solution 30 for each etching process can be kept constant, and a substrate processing apparatus with less process variation can be provided.

### [Method for Substrate Processing]

Hereinafter, a method for substrate processing using the substrate processing apparatus 1 according to the present embodiment will be described. The method for substrate processing of the present embodiment is performed, for example, as a part of a method for manufacturing a semiconductor device.

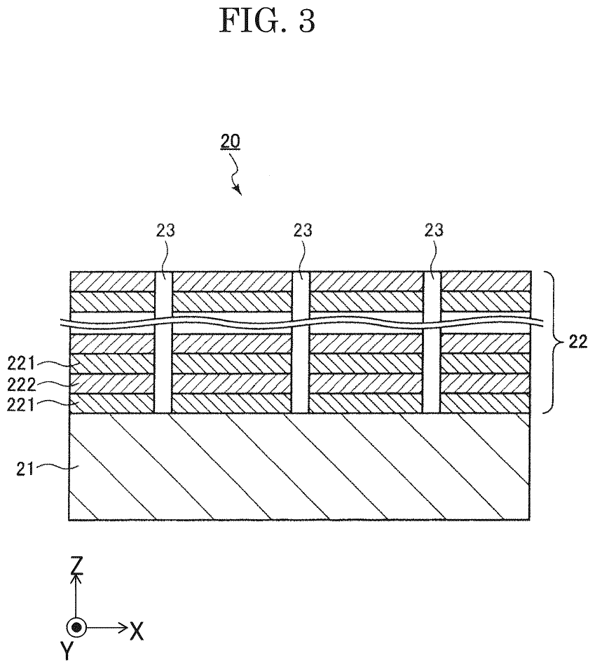

FIG. 3 is a cross-sectional view of the substrate 20 to be subjected to the etching process. The substrate 20 is, for example, a semiconductor substrate for manufacturing a stacked memory in which electrode layers are stacked. As shown in FIG. 3, the substrate 20 includes a silicon substrate 21 and a stacked film 22. The stacked film 22 includes a silicon oxide film 221 and the silicon nitride film 222 that are alternately stacked. Further, the substrate 20 has a trench 23 penetrating through the stacked film 22.

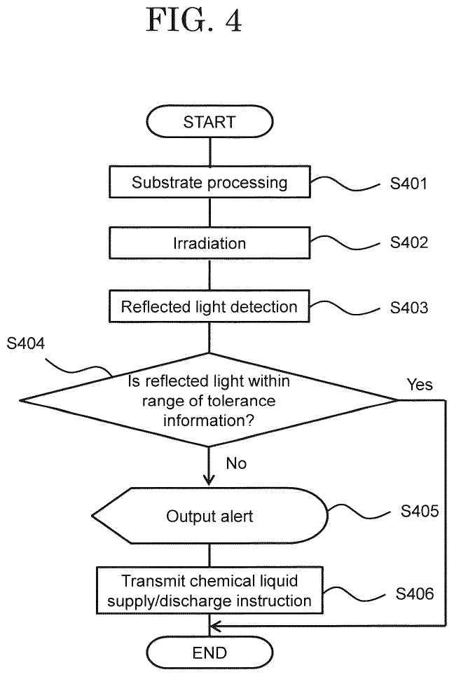

FIG. 4 is a flowchart showing a method for substrate processing. First, the substrate 20 is etched (S401). The substrate 20 held by the holder 17 is accommodated in the inner tank 111 by the lifting operation of the lifting part 171. The substrate 20 is immersed in the phosphoric acid solution 30 stored in the inner tank 111. The phosphoric acid solution 30 infiltrates into the stacked film 22 from the trench 23 of the substrate 20. As a result, the silicon nitride film 222 is removed. In this case, the dissolved silicon nitride film 222 increases silica concentration in the phosphoric acid solution 30.

The phosphoric acid solution 30 includes, for example, an additive that adsorbs on a surface of the silicon oxide film 221. The additive is adsorbed on the surface of the silicon oxide film 221 exposed by removing the silicon nitride film 222. The kind of the additive is not particularly limited. A material of the additive may be, for example, a silane coupling agent. Concentration of the additive in the phosphoric acid solution 30 is lowered by repeating the processing and by adsorbing the additive to the substrate 20. In addition, a dynamic contact angle of the phosphoric acid solution 30 (how the phosphoric acid solution 30 runs out on the substrate 20) is changed by adsorption of the additive to the substrate 20. In addition, in a space from which the silicon nitride film 222 is removed, an electrode layer is formed by a process after using another device.

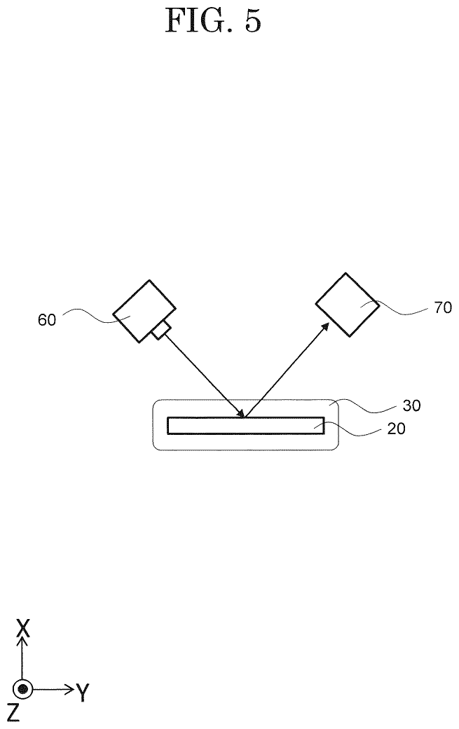

The substrate 20 is taken out from the inner tank 111 by the lifting operation of the lifting part 171 after the etching process is completed, and is irradiated with light by the light irradiation part 60 (S402). FIG. 5 is a diagram for explaining methods of light irradiation and light detection. The phosphoric acid solution 30 remains on the surface of the substrate 20 immediately after taking out from the inner tank 111. An amount of the phosphoric acid solution 30 remaining on the surface of the substrate 20 varies depending on a state of the surface of the substrate 20 and composition of the phosphoric acid solution 30. The composition of the phosphoric acid solution 30 varies depending on the etching process. Therefore, the light irradiated by the light irradiation part 60 is incident on the back surface of the substrate 20 opposite to the main surface via the phosphoric acid solution 30 on the surface of the substrate 20.

Light reflected by the back surface of the substrate 20 is detected by the light detection device 70 (S403). Reflectance obtained from intensity of the reflected light detected by the light detection part 70 varies depending on the amount and composition of the phosphoric acid solution 30 on the surface of the substrate 20. The reflectance obtained from the intensity of the reflected light detected by the light detection part 70 is transmitted to the control device 50.

The control device 50 determines whether the received reflectance is within tolerance information. In the case where the reflectance is within a range of the tolerance information, the substrate processing is ended and the subsequent substrate processing is started.

In the case where the reflectance is out of the range of the tolerance information, an alert may be indicating that the phosphoric acid solution 30 is not suitable for the subsequent etching process (S405). However, the present disclosure is not limited thereto, and the process may automatically proceed to the next step.

In the case where the reflectance is out of the range of the tolerance information, the control device 50 transmits a chemical liquid supply instruction to the chemical liquid supply device 14, and transmits a chemical liquid discharge instruction to the valve 19 (S406). The valve 19 that has received the chemical liquid discharge instruction discharges a specified amount of the phosphoric acid solution 30, and the chemical liquid supply device 14 that has received the chemical liquid supply instruction injects a specified amount of the chemical (for example, water, phosphoric acid liquid, additive, or phosphoric acid solution (the phosphoric acid liquid and additive)) into the outer tank 112.

The water, the phosphoric acid liquid, the additive, or the phosphoric acid solution (the phosphoric acid liquid and additive) introduced into the outer tank 112 is mixed with the phosphoric acid solution 30 remaining in the inner tank 111 via the circulation path 12 and circulated in the processing tank 11, whereby the phosphoric acid solution 30 can be optimized for the subsequent substrate processing. The phosphoric acid solution 30 overflowing from the inner tank 111 is collected into the outer tank 112. The phosphoric acid solution 30 collected into the outer tank 112 is sucked by the pump 15 and sent to the heating part 13. The heating part 13 heats the phosphoric acid solution 30. The phosphoric acid solution 30 heated by the heating part 13 is circulated inside the inner tank 111 by the pump 15.

The tolerance information of the reflectance may be obtained by sampling correlation data between the reflectance and pattern analysis results of the substrate 20 in advance. However, the present disclosure is not limited thereto, and the tolerance information of the reflectance may be obtained by sampling correlation data between the reflectance and silica concentration or etching rate of a silicon oxide film in advance. The previously obtained correlation data may be stored, for example, in the control device 50, and in this case, based on the obtained reflectance and the previously stored correlation data, it may be determined whether it is within or outside the range of the tolerance information, and an optimum supply amount of the chemical may be determined.

A method for substrate processing using the substrate processing apparatus 1 according to the present embodiment can obtain reflectance by irradiating light to the substrate 20 immediately after the etching process by the light irradiation part 60 and detecting the reflected light by the light detection part 70. Since the reflectance varies depending on an amount and composition of the phosphoric acid solution 30 remaining on the surface of the substrate 20, a state of the phosphoric acid solution 30 after the etching process that cannot be detected by the existing method can be grasped. By controlling amounts of the water, the phosphoric acid liquid, the additive, or the phosphoric acid solution (the phosphoric acid liquid and additive) supplied by the chemical liquid supply device 14 and a discharge amount of the phosphoric acid solution 30 by the valve 19 according to the reflectance, a state of the phosphoric acid solution 30 for each etching process can be kept constant, and a method for substrate processing with less process variation can be provided.

In the present embodiment, a configuration has been described in which the light detection part 70 detects the reflected light to obtain the reflectance and transmits the obtained reflectance to the control device 50. However, the present disclosure is not limited thereto, and the light detection part 70 may directly transmit the intensity of the detected reflected light to the control device 50. The control device 50 may obtain the reflectance from the intensity of the received reflected light and determine whether the obtained reflectance is within the range of the tolerance information. In addition, the tolerance information is not limited to the reflectance, and may be the intensity or absorbance of the reflected light. In this case, the control device 50 may determine whether the intensity of the received reflected light is within the range of the tolerance information, and may obtain the absorbance from the intensity of the received reflected light and determine whether the obtained absorbance is within the range of the tolerance information.

### [Modification 1]

A configuration of the substrate processing apparatus according to the present modification is the same as the configuration of the substrate processing apparatus according to the first embodiment. A method for substrate processing according to the present modification is the same as the method for substrate processing according to the first embodiment except that the reflected light is measured over time. Descriptions that are the same as those in the first embodiment are omitted, and parts different from those in the method for substrate processing according to the first embodiment will be described here.

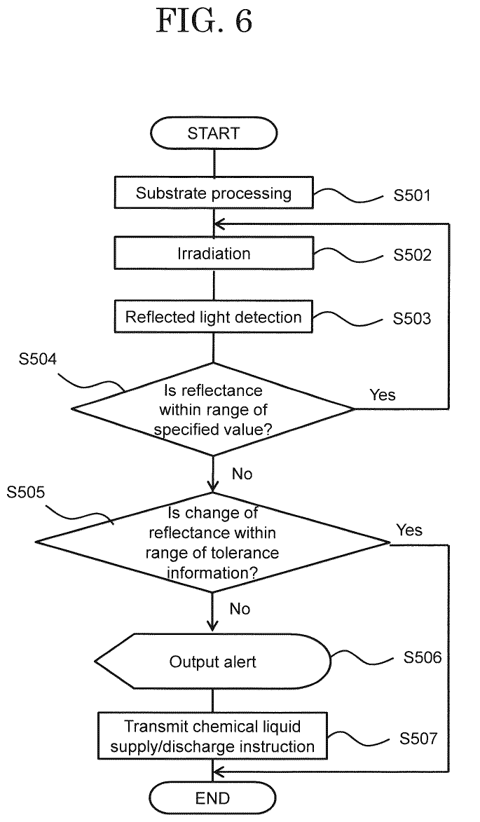

FIG. 6 is a flowchart showing a method for substrate processing. An etching process (S501), an irradiation of light by the light irradiation part 60 (S502) and a detection of reflected light by the light detection part 70 (S503) of the substrate 20 are the same as those of the first embodiment, and thus explanation thereof is omitted. Reflectance obtained from intensity of the reflected light detected by the light detection part 70 is transmitted to the control device 50.

The controller 50 to determine if the received reflectance is within a range of a specified value (S504). In the case where the reflectance is within the range of the specified value, the light irradiation by the light irradiation part 60 (S502), and the detection of the reflected light by the light detection part 70 (S503) are repeated over time.

A predetermined value of the reflectance may be a lower limit value or an upper limit value of reflectance that changes with time sampled in advance. However, the present disclosure is not limited thereto, and it may be determined whether or not the time when the reflectance is received is within a predetermined time.

In the case where the reflectance is out of the range of the specified value, the controller 50 determines whether change rate of the received reflectance is within the range of the tolerance information (S505). When the change rate of the reflectance is within the range of the tolerance information, the substrate processing is ended and the subsequent substrate processing is started.

If the change rate of the reflectance is out of the range of the tolerance information, an alert may be indicating that the phosphoric acid solution 30 is not suitable for the subsequent etching process may be output (S506). However, the present disclosure is not limited thereto, and the process may automatically proceed to the next step.

In the case where the change rate of the reflectance is out of the range of the tolerance information, the control device 50 transmits a chemical liquid supply instruction to the chemical liquid supply device 14, and transmits a chemical liquid discharge instruction to the valve 19 (S506). The valve 19 that has received the chemical liquid discharge instruction discharges a specified amount of the phosphoric acid solution 30, and the chemical liquid supply device 14 that has received the chemical liquid supply instruction supplies a specified amount of water, phosphoric acid liquid, additive, or phosphoric acid solution (the phosphoric acid liquid and additive) to the outer tank 112.

The water, the phosphoric acid liquid, the additive, or the phosphoric acid solution (the phosphoric acid liquid and additive) introduced into the outer tank 112 is mixed with the phosphoric acid solution 30 via the circulation path 12 and circulated in the processing tank 11, whereby the phosphoric acid solution 30 can be optimized for the subsequent substrate processing.

The tolerance information of the change rate of the reflectance may be obtained by sampling correlation data between the change rate of the reflectance and a pattern analysis result of the substrate 20 in advance.

In a method for substrate processing using the substrate processing apparatus 1 according to the present modification, light is irradiated onto the substrate 20 immediately after the etching process by the light irradiation part 60 and the reflected light is detected over time by the light detection part 70, whereby change rate of reflectance can be obtained. Since the reflectance varies depending on an amount and composition of the phosphoric acid solution 30 remaining on the surface of the substrate 20, a state of the phosphoric acid solution 30 after the etching process that cannot be detected by the existing method can be grasped. By controlling amounts of water, phosphoric acid liquid, additive, or phosphoric acid solution (the phosphoric acid liquid and additive) supplied by the chemical liquid supply device 14 and a discharge amount of the phosphoric acid solution 30 by the valve 19 according to the change rate of reflectance, a state of the phosphoric acid solution 30 for each etching process can be kept constant, and a method for substrate processing with less process variation can be provided.

In the present modification, a configuration has been described in which the light detection part 70 detects the reflected light over time to obtain change rate of reflectance, and transmits the obtained change rate of the reflectance to the control device 50. However, the present disclosure is not limited thereto, and the light detection part 70 may directly transmit the intensity of the reflected light detected over time to the control device 50. In addition, the control device 50 may obtain the reflectance from the intensity of the received reflected light, and determine whether the obtained change rate of the reflectance is within a range of tolerance information. The tolerance information is not limited to the change rate of the reflectance, and may be change rate of the intensity of the reflected light, change rate of the absorbance, or the like. In this case, the control device 50 may determine whether the change rate of the intensity of the received reflected light is within the range of the tolerance information, and may obtain the change rate of the absorbance from the intensity of each received reflected light and determine whether the change rate of the absorbance obtained is within the range of the tolerance information.

What is claimed is:

1. A substrate processing apparatus comprising:
a processing tank configured to store a chemical and perform processing by immersing a substrate in the chemical;
a holder configured to hold the substrate and having a lifting part;
a chemical liquid supply device configured to supply the chemical;
a light irradiation part configured to irradiate light to the substrate taken out from the processing tank, the substrate being taken out from the processing tank by the lifting part after immersing the substrate in the chemical;
a light detection part configured to detect reflected light generated from the light being reflected by the substrate; and
a control device configured to control an amount of chemical supplied by the chemical liquid supply device in response to a detection result of the light detection part.

2. The substrate processing apparatus according to claim 1, wherein the control device controls a discharge amount of chemical in accordance with a detection result of the light detection part.

3. The substrate processing apparatus according to claim 1, wherein
the light irradiation part irradiates the light over time, and
the light detection part detects the reflected light over time.

4. The substrate processing apparatus according to claim 1,
wherein the light irradiation part irradiates the light of a plurality of wavelengths, and
the light detection part detects the reflected light of a plurality of wavelengths.

5. The substrate processing apparatus according to claim 1, wherein
the substrate has a first surface on which a laminate in which a silicon nitride film and a silicon oxide film are alternately formed is arranged, and a second surface opposite to the first surface, and
the light irradiation part irradiates the second surface of the substrate with the light.

6. The substrate processing apparatus according to claim 5, wherein the chemical is a phosphoric acid solution and includes an additive that adsorbs to the silicon oxide film.

7. A method for substrate processing comprising:
preparing a substrate processing apparatus including a processing tank configured to store a chemical and perform processing by immersing a substrate in the chemical, a holder configured to hold the substrate and having a lifting part, a chemical liquid supply device configured to supply the chemical, a light irradiation part configured to irradiate light to the substrate taken out from the processing tank by the lifting part after immersing in the chemical, a light detection part configured to detect reflected light generated from the light being reflected by the substrate, and a control device configured to control an amount of chemical supplied by the chemical liquid supply device in response to a detection result of the light detection part;
immersing the substrate in the chemical;
taking out the substrate from the chemical;
irradiating light to the substrate after taking out the substrate from the chemical; and
detecting reflected light generated from the light being reflected by the substrate.

8. The method for substrate processing according to claim 7, wherein the control device controls a discharge amount of chemical in accordance with a detection result of the light detection part.

9. The method for substrate processing according to claim 7, wherein
the light irradiation part irradiates the light over time, and
the light detection part detects the reflected light over time.

10. The method for substrate processing according to claim 7,
wherein the light irradiation part irradiates the light of a plurality of wavelengths, and
the light detection part detects the reflected light of a plurality of wavelengths.

11. The method for substrate processing according to claim 7, wherein
the substrate has a first surface on which a laminate in which a silicon nitride film and a silicon oxide film are alternately formed is arranged, and a second surface opposite to the first surface, and
the light irradiation part irradiates the second surface of the substrate with the light.

12. The method for substrate processing according to claim 11, wherein the chemical is a phosphoric acid solution and includes an additive that adsorbs to the silicon oxide film.

13. A method for manufacturing a semiconductor device comprising:
preparing a substrate processing apparatus including a processing tank configured to store a chemical and perform processing by immersing a semiconductor substrate in the chemical, a holder configured to hold the semiconductor substrate and having a lifting part, a chemical liquid supply device configured to supply the chemical, a light irradiation part configured to irradiate light to the semiconductor substrate taken out from the processing tank by the lifting part after immersing in the chemical, a light detection part configured to detect reflected light generated from the light being reflected by the semiconductor substrate, and a control device configured to control an amount of chemical supplied by the chemical liquid supply device in response to a detection result of the light detection part;
immersing the semiconductor substrate in the chemical;
taking out the semiconductor substrate from the chemical;
irradiating light to the semiconductor substrate after taking out the substrate from the chemical; and
detecting reflected light which is the light reflected.

14. The method for manufacturing the semiconductor device according to claim 13, wherein
the semiconductor substrate has a laminate in which a silicon nitride film and a silicon oxide film are alternately formed.

15. The method for manufacturing the semiconductor device according to claim 13, wherein the control device controls a discharge amount of chemical in accordance with a detection result of the light detection part.

16. The method for manufacturing the semiconductor device according to claim 13, wherein
the light irradiation part irradiates the light over time, and
the light detection part detects the reflected light over time.

17. The method for manufacturing the semiconductor device according to claim 13,
wherein the light irradiation part irradiates the light of a plurality of wavelengths, and
the light detection part detects the reflected light of a plurality of wavelengths.

18. The method for manufacturing the semiconductor device according to claim 13, wherein
the semiconductor substrate has a first surface on which a laminate in which a silicon nitride film and a silicon oxide film are alternately formed is arranged, and a second surface opposite to the first surface, and
the light irradiation part irradiates the second surface of the semiconductor substrate with the light.

19. The method for manufacturing the semiconductor device according to claim 18, wherein the chemical is a phosphoric acid solution and includes an additive that adsorbs to the silicon oxide film.
